(19) United States
(12) Patent Application Publication
(10) Pub. No.: US 2025/0175175 A1
(43) Pub. Date: May 29, 2025

(54) APERTURE TUNER CIRCUIT

(71) Applicant: MEDIATEK INC., Hsinchu City (TW)

(72) Inventors: Kuo-Hao Chen, Hsinchu City (TW); Chung-Yu Hung, Hsinchu City (TW)

(73) Assignee: MEDIATEK INC., Hsinchu City (TW)

(21) Appl. No.: 18/959,677

(22) Filed: Nov. 26, 2024

Related U.S. Application Data
(60) Provisional application No. 63/603,674, filed on Nov. 29, 2023.

(51) Int. Cl. H03K 17/51

(52) U.S. Cl. CPC H03K 17/51; H03K 2017/515; H03K 2217/9401

(57) ABSTRACT

An aperture tuner circuit includes a plurality of switching terminals, at least one auxiliary terminal, at least one open/short/load (OSL) calibration circuit and a switch network. The OSL calibration circuit is connected to the at least one auxiliary terminal and selectively configurable to provide one of a predetermined open path, a predetermined short path and predetermined load to the aperture tuner circuit. The switch network is connected to the plurality of switching terminals and configured to selectively establish and reconfigure signal paths between the switching terminals.

### CROSS REFERENCE TO RELATED APPLICATIONS

This application claims the benefit of U.S. Provisional Application No. 63/603,674, filed on Nov. 29, 2023. The content of the application is incorporated herein by reference.

### BACKGROUND

The present invention relates to wireless communications, and more particularly to an aperture tuner circuit.

In recent years, modern mobile devices have evolved to support an increasingly diverse array of wireless communication applications, including but not limited to cellular networks (2G/3G/4G/5G), Wi-Fi (2.4 GHz/5 GHz/6 GHz), Bluetooth, Global Navigation Satellite Systems (GNSS) and Near Field Communication (NFC) protocols. These applications operate across multiple frequency bands, ranging from sub-1 GHz to millimeter-wave frequencies, creating significant challenges for antenna design and implementation within the confined space of mobile devices. To address these challenges, antenna aperture tuning has emerged as a critical technology. Antenna aperture tuning is a process through which a resonant frequency of an antenna can be dynamically modified to accommodate specific applications and frequency bands. This technology enables a single antenna to efficiently operate across multiple frequency bands by adjusting its electrical characteristics in real-time.

The fundamental principle of aperture tuning involves altering an electrical length of an antenna to adjust its resonant frequency. This adjustment modifies the antenna's impedance matching characteristics and radiation pattern, thereby improving performance metrics such as total radiated power (TRP) and total isotropic sensitivity (TIS). These improvements are achieved by either increasing the antenna's effective aperture size or optimizing its radiation pattern for specific frequency bands, resulting in enhanced signal quality and improved power efficiency. However, as wireless communication standards continue to evolve and the demand for multi-band operation increases, there is a pressing need for high-performance aperture tuner circuits capable of providing precise and efficient antenna tuning across multiple frequency bands.

### SUMMARY

With this in mind, it is one object of the present invention to provide an aperture tuner circuit with enhanced calibration capabilities. The aperture tuner circuit of the present invention provides dedicated auxiliary terminals for interfacing with built-in open/short/load (OSL) calibration circuits, enabling precise and flexible calibration operations. Specifically, a built-in calibration device can utilize these dedicated auxiliary terminals to perform high-precision calibration procedures on the aperture tuner circuit, thereby optimizing impedance matching accuracy and improving overall radio frequency (RF) performance across multiple frequency bands.

According to one embodiment, an aperture tuner circuit is provided. The aperture tuner circuit comprises: a plurality of switching terminals, at least one auxiliary terminal, at least one open/short/load (OSL) calibration circuit and a switch network. The at least one OSL calibration circuit is connected to the at least one auxiliary terminal and selectively configurable to provide one of a predetermined open path, a predetermined short path and a predetermined load to the aperture tuner circuit. The switch network is connected to the plurality of switching terminals, and configured to selectively establish and reconfigure signal paths between the switching terminals.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a schematic diagram of an aperture tuner circuit according to one embodiment of the present invention.

FIG. 2A depicts a first implementation of the aperture tuner circuit of FIG. 1 according to one embodiment of the present invention.

FIG. 2B depicts a second implementation of the aperture tuner circuit of FIG. 1 according to one embodiment of the present invention.

FIG. 2C depicts circuit diagrams of various implementations of a capacitance tuning circuit of FIG. 2B according to embodiments of the present invention.

FIG. 2D depicts a third implementation of the aperture tuner circuit of FIG. 1 according to one embodiment of the present invention.

FIG. 3 depicts a schematic diagram of an aperture tuner circuit according to another embodiment of the present invention.

FIG. 4A depicts a first implementation of the aperture tuner circuit of FIG. 3 according to one embodiment of the present invention.

FIG. 4B depicts circuit diagrams of various implementations of capacitance tuning circuits of FIG. 4A according to embodiments of the present invention.

FIG. 4C depicts a second implementation of the aperture tuner circuit of FIG. 3 according to one embodiment of the present invention.

FIG. 4D depicts a third implementation of the aperture tuner circuit of FIG. 3 according to one embodiment of the present invention.

FIG. 4E depicts a fourth implementation of the aperture tuner circuit of FIG. 3 according to one embodiment of the present invention.

### DETAILED DESCRIPTION

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

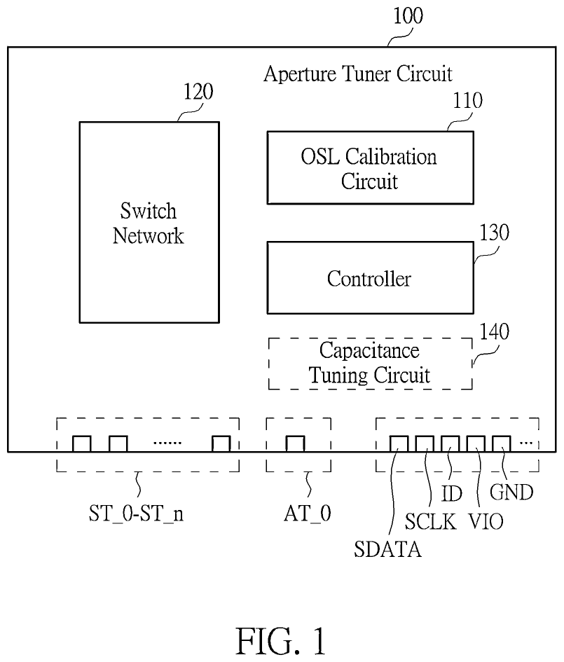

Please refer to FIG. 1, which depicts an aperture tuner circuit according to one embodiment of the present invention. As depicted, an aperture tuner circuit 100 comprises an open/short/load (OSL) calibration circuit 110, a switch network 120, a controller 130 and an optional capacitance tuning circuit 140. The aperture tuner circuit 100 also has a plurality of switching terminals ST_0-ST_n and an auxiliary terminal AT_0. According to various embodiments, the switching terminals ST_0-ST_n and the auxiliary terminal AT_0 could be implemented in various interconnection forms including, but not limited to, conductive pins (e.g., through-hole pins, surface-mount pins, gull-wing leads, J-leads, I-leads), contact pads (e.g., wire bonding pads, flip-chip pads, land grid array (LGA) contact pads), solder balls, copper pillars, or other suitable electrical connection means. Moreover, the aperture tuner circuit 100 may comprise communication terminals SDATA, SCLCK and ID for implementing an interface protocol to facilitate unidirectional or bidirectional communication between a host device (not shown) and the controller 130, a power terminal VIO for receiving power supply, and a ground terminal GND served as electrical ground reference.

In some embodiments, at least one of the switching terminals ST_0-ST_n is configurable to be connected to a tuning element, wherein the tuning element comprises at least one of: a fixed-value capacitor, a variable capacitor, a digitally tunable capacitor (DTC), a fixed-value inductor, a variable inductor, or any combination thereof for tuning/modify a resonant frequency of an antenna. The tuning element may be implemented as discrete components or as integrated passive devices (IPDs). At least one of the switching terminals ST_0-ST_n is configurable to be connected to an antenna element to be tuned, wherein the antenna element may comprise, but is not limited to, a monopole antenna, a dipole antenna, a patch antenna, a planar inverted-F antenna, a loop antenna, or other types of antennas operating in predetermined frequency bands including, but not limited to, cellular bands (such as LTE, 5G NR), Wi-Fi bands, GPS bands, or Bluetooth bands.

In addition, the auxiliary terminal AT_0 could be selectively connected to any of the switching terminals ST_0-ST_n or an built-in calibration device, thereby facilitating a calibration operation on the aperture tuner circuit 100. The built-in calibration device may comprise equipment capable of performing RF scattering parameter measurements. The calibration operation may include, but is not limited to: open/short/load circuit characterization.

The OSL calibration circuit 110 is connected to the auxiliary terminal AT_0 and selectively configurable to provide one of: a predetermined open path, a predetermined short path, and a predetermined load to the aperture tuner circuit 100 for the purpose of tuner calibration. The switch network 120 is connected to the plurality of switching terminals ST_0-ST_n, and configured to selectively establish and reconfigure signal paths between the switching terminals ST_0-ST_n.

The controller 130 is configured to control configurations of the OSL calibration circuit 110 and the switch network 120 through digital control signals, thereby establishing and reconfiguring signal paths provided by the switch network 120 and controlling the OSL calibration circuit 110 to provide one of the predetermined open path, the predetermined short path and the predetermined load to the aperture tuner circuit 100. In some embodiments, the controller 130 could be compliant with Mobile Industry Processor Interface RF Front-End Control Interface (MIPI RFFE) specification version 2.1 or above, which utilizes communication terminals ID, SDATA and SCLK to communicate with a host device (not shown) through a two-wire serial interface. However, the communication terminals of the aperture tuner circuit 100 are controller-dependent, and the number and the type of communication terminals may be implemented through other interface protocols including, but not limited to: Serial Peripheral Interface (SPI), Inter-Integrated Circuit (I2C) interface, General Purpose I/O (GPIO) based interface.

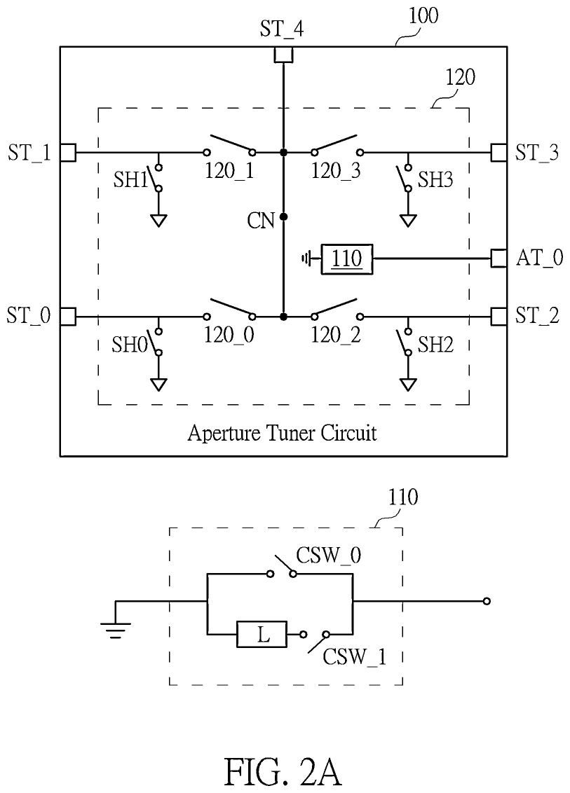

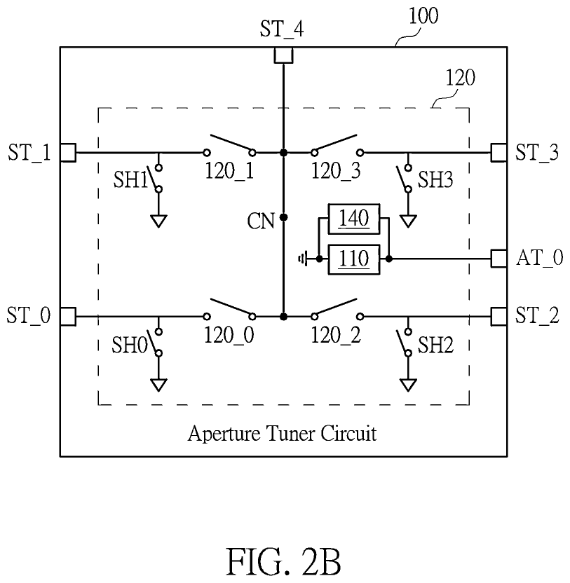

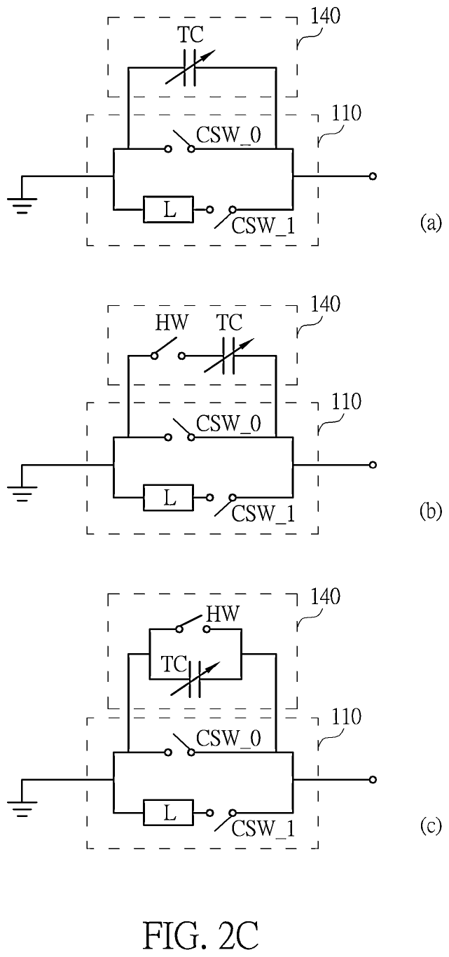

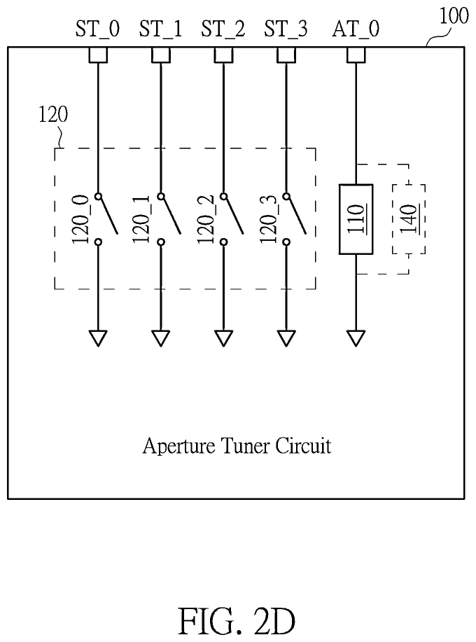

FIG. 2A depicts a first implementation of the aperture tuner circuit of FIG. 1 according to one embodiment of the present invention. In this implementation, the switch network 120 is configured as a single-pole, four-throw (SP4T) switch architecture and comprises four switches 120_0-120_3. Each of switches 120_0-120_3 has a first end connected to a common node CN of the switch network 120 and a second end connected to a respective one of switching terminals ST_0-ST_3. In addition, a switching terminal ST_4 is connected to the common node CN of the switch network 120 through wire/trace. Through signal paths provided by the switches 120_0-120_3, the aperture tuner circuit 100 can apply a variety of impedances to the antenna to adjust a resonant frequency of the antenna, enabling its multiple frequency band operations.

Please note that, according to various embodiments of the present invention, the number of switches included in the switch network 120 may be different from the above implementation. In some implementations, the switch network 120 could comprise more switches, and be configured as a single-pole, multi-throw switch architecture (e.g., SPnT switch, where n≥2), with each of switches connected between the common node CN and a respective one of switching terminals ST_0-ST_n.

In the first implementation of the aperture tuner circuit 100 shown by FIG. 2A, the switch network 120 optionally comprises shunt switches SH0-SH3, each connected between a respective one of the switching terminals ST_0-ST_3 and the ground. A conductive state of each of the shunt switches SH0-SH3 is complementary to a conductive state of a corresponding one of the switches 120_0-120_3. For example, if the switch 120_0 is in a non-conductive state (e.g., high impedance state), the shunt switch SH0 would be in a conductive state (e.g., low impedance state). One of purposes of the shunt switches SH0-SH3 is to prevent resonance at unwanted frequency when the switches 120_0-120_3 are in a non-conductive state.

The OSL calibration circuit 110 is connected between the auxiliary terminal AT_0 and the ground. As illustrated, the OSL calibration circuit 110 comprises switches CSW_0 and CSW_1, and a predetermined load element L, where: the switch CSW_1 is connected in series with the load element L, the switch CSW_0 is connected in parallel with the series combination of CSW_1 and load element L. If both switches CSW_0-CSW_1 are in a non-conductive state, the OSL calibration circuit 110 could provide a predetermined open path to the aperture tuner circuit 100. If the switch CSW_0 is in a conductive state and the switch CSW_1 is in a non-conductive state, the OSL calibration circuit 110 could provide a predetermined short path to the aperture tuner circuit 100 (from the auxiliary terminal AT_0 to the ground). If the switch CSW_1 is in a conductive state and the switch CSW_0 is in a non-conductive state, the OSL calibration circuit 110 could provide a predetermined load to the aperture tuner circuit 100. Moreover, the auxiliary terminal AT_0 could be selectively connected to any of the switching terminals ST_0-ST_4, thereby facilitating a calibration operation on the aperture tuner circuit 100 through the built-in calibration device.

FIG. 2B depicts a second implementation of the aperture tuner circuit of FIG. 1 according to one embodiment of the present invention. Compared to the first implementation shown by FIG. 2A, the aperture tuner circuit 100 of the second implementation further comprises a capacitance tuning circuit 140 that is connected in parallel with the OSL calibration circuit 110 for providing additional impedance tuning capability.

FIG. 2C depicts circuit diagrams of various implementations of the capacitance tuning circuit 140 according to embodiments of the present invention. In implementation (a), the capacitance tuning circuit 140 comprises at least one tunable capacitor TC (which can be a digitally tunable capacitor or switched capacitor array that is controllable through a digital interface by the controller 130) and the at least one tunable capacitor TC is connected in parallel with the OSL calibration circuit 110. In implementation (b), the capacitance tuning circuit 140 comprises at least one tunable capacitor TC and at least one switch HW. The at least one tunable capacitor TC and the at least one switch HW are connected in series. In addition, the series combination of the at least one tunable capacitor TC and the at least one switch HW is further connected in parallel with the OSL calibration circuit 110. In implementation (c), the capacitance tuning circuit 140 comprises at least one tunable capacitor TC and at least one switch HW. The at least one tunable capacitor TC and the at least one switch HW are connected in parallel. In addition, the parallel combination of the at least one tunable capacitor TC and the at least one switch HW is connected in parallel with the OSL calibration circuit 110.

FIG. 2D depicts a third implementation of the aperture tuner circuit of FIG. 1 according to one embodiment of the present invention. In this implementation, the switch network 120 is configured as four single-pole, single-throw (SPST) switches and comprises four switches 120_0-120_3. Each of switches 120_0-120_3 has a first end connected to the ground and a second end connected to a respective one of switching terminals ST_0-ST_3. Through signal paths provided by the switches 120_0-120_3, the aperture tuner circuit 100 can apply a variety of impedances to the antenna to adjust the resonant frequency of the antenna, enabling multiple frequency band operations.

In some embodiments, the number of switches included in the switch network 120 may be different from the implementation shown by FIG. 2D. For example, the switch network 120 could comprise more switches, configured as “N”×SPST switches (where N≥1), with each of switches connected between the ground and a respective one of switching terminals ST_0-ST_n.

In addition, the OSL calibration circuit 110 is connected between the ground and the auxiliary terminal AT_0. Similarly, the OSL calibration circuit 110 comprises switches CSW_0-CSW_1 and a load element L as illustrated in FIG. 2A, thereby providing one of a predetermined open path, a predetermined short path and a predetermined load to the aperture tuner circuit 100.

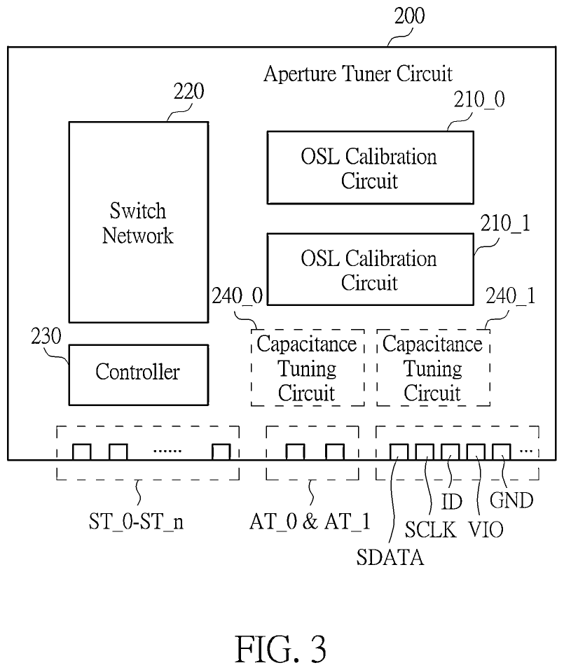

FIG. 3 depicts a schematic diagram of an aperture tuner circuit according to another embodiment of the present invention. As depicted, an aperture tuner circuit 200 comprises OSL calibration circuits 210_0 and 210_1, a switch network 220 and a controller 230. Compared to the embodiment of FIG. 1, the aperture tuner circuit 200 comprises more than one OSL calibration circuits, namely OSL calibration circuits 210_0 and 210_1. The OSL calibration circuits 210_0 and 210_1 are connected to auxiliary terminals AT_0 and AT_1, respectively.

Besides, the aperture tuner circuit 200 also has a plurality of switching terminals ST_0-ST_n, communication terminals SDATA, SCLCK and ID for implementing an interface protocol for facilitating communication with a host device (not shown), a power terminal VIO for receiving power supply, and a ground terminal GND served as electrical ground reference. All the terminals of the aperture tuner circuit 200 could be implemented in various interconnection forms including conductive pins, contact pads, solder balls, copper pillars, or other suitable electrical connection means.

In some embodiments, at least one of the switching terminals ST_0-ST_n is configurable to be connected to a tuning element, wherein the tuning element comprises at least one of: a fixed-value capacitor, a variable capacitor, a DTC, a fixed-value inductor, a variable inductor, or any combination thereof for impedance matching purposes. The tuning element may be implemented as discrete components or as integrated IPDs. At least one of the switching terminals ST_0-ST_n is configurable to be connected to an antenna element to be tuned, wherein the antenna element may comprise, but is not limited to, a monopole antenna, a dipole antenna, a patch antenna, a planar inverted-F antenna, a loop antenna, or other types of antennas operating in predetermined frequency bands including, but not limited to, cellular bands (such as LTE, 5G NR), Wi-Fi bands, GPS bands, or Bluetooth bands.

In addition, the auxiliary terminals AT_0 and AT_1 could be selectively connected to any of the switching terminals ST_0-ST_n or a built-in calibration device, thereby facilitating a calibration operation on the aperture tuner circuit 200.

Each of the OSL calibration circuits 210_0 and 210_1 is selectively configurable to provide one of: a predetermined open path, a predetermined short path, and a predetermined load to the aperture tuner circuit 100 for the purpose of tuner calibration. The switch network 220 is connected to the plurality of switching terminals ST_0-ST_n, and configured to selectively establish and reconfigure signal paths between the switching terminals. The controller 230 (which may be compliant with MIPI RFFE specification) is configured to control configurations of the OSL calibration circuits 210_0-210_1 and the switch network 220 through digital control signals, thereby establishing and reconfiguring signal paths provided by the switch network 220 and controlling the OSL calibration circuits 210_0-210_1 to provide one of the predetermined open path, the predetermined short path and the predetermined load to the aperture tuner circuit 200.

Optionally, the aperture tuner circuit 200 may further comprise capacitance tuning circuits 240_0 and 240_1. The capacitance tuning circuit 240_0 could be connected in series with the OSL calibration circuit 210_0, while the capacitance tuning circuit 240_1 could be connected in series with the OSL calibration circuit 210_1. In some embodiments, the aperture tuner circuit 200 may comprise only one capacitance tuning circuit while retaining multiple OSL calibration circuits. This configuration could provide a cost-optimized solution that maintains essential calibration accuracy while reducing circuit and control complexity and cost.

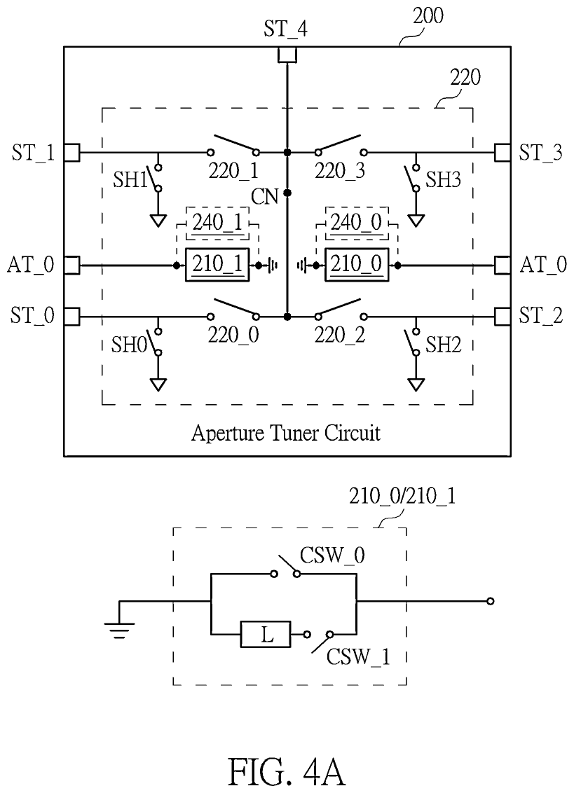

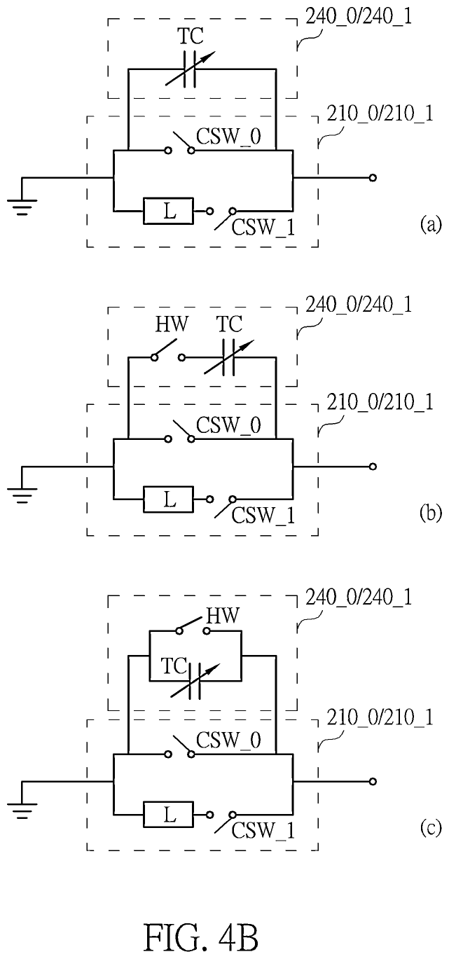

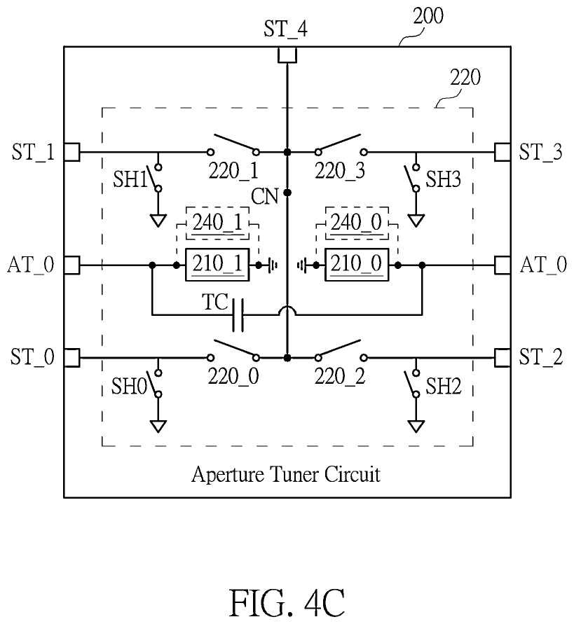

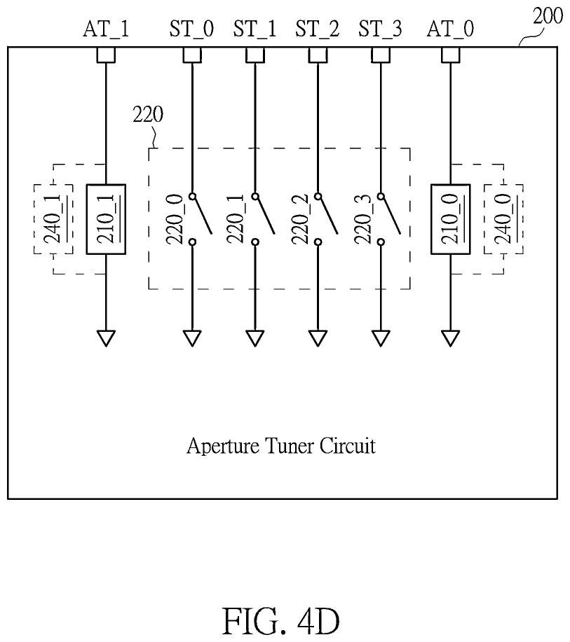

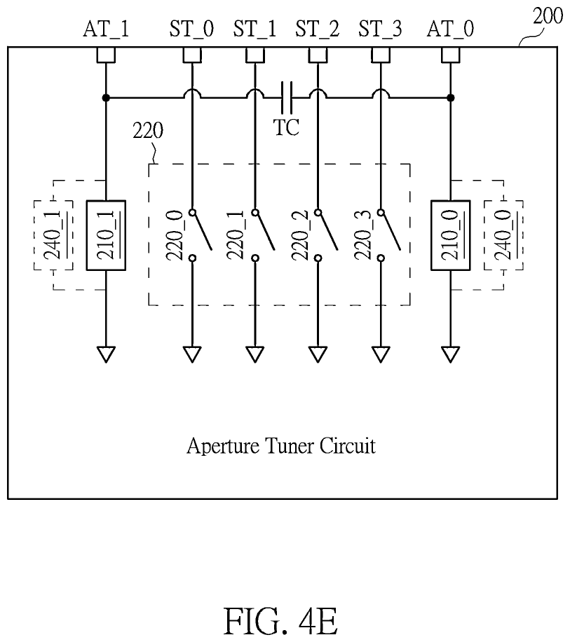

FIG. 4A depicts a first implementation of the aperture tuner circuit of FIG. 3 according to one embodiment of the present invention. In this implementation, the switch network 220 is configured as a single-pole, four-throw (SP4T) switch architecture and comprises four switches 220_0-220_3. Each of switches 220_0-220_3 has a first end connected to a common node CN of the switch network 220 and a second end connected to a respective one of switching terminals ST_0-ST_3. In addition, a switching terminal ST_4 is connected to the common node CN of the switch network 220 through wire/trace. Through signal paths provided by the switches 220_0-220_3, the aperture tuner circuit 200 can apply a variety of impedances to the antenna to adjust its resonant frequency, enabling multiple frequency band operations.

According to various embodiments of the present invention, the number of switches included in the switch network 220 may be different from the above implementation. In some implementations, the switch network 220 could comprise more switches, and be configured as a single-pole, multi-throw switch architecture (e.g., SPnT switch, where n≥2), with each of switches connected between the common node CN and a respective one of switching terminals ST_0-ST_n.

In the first implementation of the aperture tuner circuit 200 shown by FIG. 4A, the switch network 220 optionally comprises shunt switches SH0-SH3, each connected between a respective one of the switching terminals ST_0-ST_3 and the ground, wherein a conductive state of each of the shunt switches SH0-SH3 is complementary to a conductive state of a corresponding one of the switches 220_0-220_3. Each shunt switch is to prevent resonance at unwanted frequency when the switches 220_0-220_3 are in a non-conductive state.

The OSL calibration circuit 210_0 is connected between the auxiliary terminal AT_0 and the ground, while The OSL calibration circuit 210_1 is connected between the auxiliary terminal AT_1 and the ground. As illustrated, the OSL calibration circuits 210_0 and 210_1 could have structure identical to that of the OSL calibration circuit 110 shown by FIG. 2A. Each of the OSL calibration circuits 210_0 and 210_1 is configurable to selectively provide one of a predetermined open path, a predetermined short path and a predetermined load to the aperture tuner circuit 200 based on the conductive states of the switches CSW_0 and CSW_1. Moreover, each of the auxiliary terminals AT_0 and AT_1 could be selectively connected to any of the switching terminals ST_0-ST_4, thereby facilitating a calibration operation on the aperture tuner circuit 200 through the built-in calibration device.

In some embodiments, the aperture tuner circuit 200 further comprises one or more capacitance tuning circuits for providing additional impedance tuning capability and enhanced calibration accuracy. In case of one capacitance tuning circuit, one capacitance tuning circuit 240_0 may be connected in parallel with either the OSL calibration circuit 210_0 or the OSL calibration circuit 210_1. In case of multiple capacitance tuning circuits, capacitance tuning circuits 240_0 and 240_1 are connected in parallel with the OSL calibration circuits 210_0 and 210_1, respectively.

FIG. 4B depicts circuit diagrams of various implementations of capacitance tuning circuits of FIG. 4A according to embodiments of the present invention. In implementation (a), the capacitance tuning circuits 240_0/240_1 comprise at least one tunable capacitor TC (which can be a digitally tunable capacitor or switched capacitor array that is controllable through a digital interface) and the at least one tunable capacitor TC is connected in parallel with the OSL calibration circuits 210_0/210_1. In implementation (b), the capacitance tuning circuits 240_0/240_1 comprise at least one tunable capacitor TC and at least one switch HW. The at least one tunable capacitor TC and the at least one switch HW are connected in series. In addition, the series combination of the at least one tunable capacitor TC and the at least one switch HW is further connected in parallel with the OSL calibration circuits 210_0/210_1. In implementation (c), the capacitance tuning circuits 240_0/240_1 comprises at least one tunable capacitor TC and at least one switch HW. The at least one tunable capacitor TC and the at least one switch HW are connected in parallel. In addition, the parallel combination of the at least one tunable capacitor TC and the at least one switch HW is connected in parallel with the OSL calibration circuits 210_0/210_1.

Please note that the implementation of the combination of the OSL calibration circuit 210_0 and the capacitance tuning circuit 240_0 could be different from the implementation of the combination of the OSL calibration circuit 210_1 and the capacitance tuning circuit 240_1. For example, the implementation of the combination of the OSL calibration circuit 210_0 and the capacitance tuning circuit 240_0 can be based on implementation (a), while the implementation of the combination of the OSL calibration circuit 210_1 and the capacitance tuning circuit 240_1 can based on implementation (b) or (c).

FIG. 4C depicts a second implementation of the aperture tuner circuit of FIG. 3 according to one embodiment of the present invention. Compared to the first implementation of the aperture tuner circuit 200 shown by FIG. 4A, the aperture turner circuit 200 further comprises a tunable capacitor TC (which can be a digitally tunable capacitor or switched capacitor array that is controllable through a digital interface by the controller 230) connected between the auxiliary terminals AT_0 and AT_1. The tunable capacitor TC between the auxiliary terminals AT_0 and AT_1 is configured to adjust an impedance of the aperture tuner circuit 200.

FIG. 4D depicts a third implementation of the aperture tuner circuit of FIG. 3 according to one embodiment of the present invention. In this implementation, the switch network 220 is configured as four single-pole, single-throw (SPST) switches and comprises four switches 220_0-220_3. Each of switches 220_0-220_3 has a first end connected to the ground and a second end connected to a respective one of switching terminals ST_0-ST_3. Through signal paths provided by the switches 220_0-220_3, the aperture tuner circuit 200 can apply a variety of impedances to the antenna to adjust its resonant frequency, enabling different frequency band operations.

In some embodiments, the number of switches included in the switch network 220 may be different from the implementation shown by FIG. 4D. For example, the switch network 120 could comprise more switches, configured as “N”×SPST switches (where N≥1), with each of switches connected between the ground and a respective one of switching terminals ST_0-ST_n.

In this implementation, the aperture tuner circuit 200 may optionally comprise one or more capacitance tuning circuits 240_0 and 240_1. In case of one capacitance tuning circuit, capacitance tuning circuit 230_0 may be connected in parallel with either the OSL calibration circuit 210_0 or the OSL calibration circuit 210_1. In case of multiple capacitance tuning circuits, capacitance tuning circuits 240_0 and 240_1 are connected in parallel with the OSL calibration circuits 210_0 and 210_1, respectively. Moreover, the auxiliary terminals AT_0 and AT_1 could be connected to any of the switching terminals ST_0-ST_4 or an external calibration device, thereby facilitating a calibration operation on the aperture tuner circuit 200 through an external calibration device.

In the implementation of FIG. 4D, the switch network 220 optionally comprises shunt switches (not shown), each connected to a respective one of the switching terminals ST_0-ST_3 and connected in parallel with a respective one of the switches 220_0-220_3. Each shunt switch here is intended for enhancing RF isolation.

FIG. 4E depicts a fourth implementation of the aperture tuner circuit of FIG. 3 according to one embodiment of the present invention. Compared to the third implement of the aperture tuner circuit 200 shown by FIG. 4D, there is a tunable capacitor TC connected between the auxiliary terminals AT_0 and AT_1 for the purpose of adjusting an impedance of the aperture tuner circuit 200.

In view of the above, the aperture tuner circuit of the present invention introduces several innovative features that significantly advance the state of the art in antenna tuning technology. By implementing dedicated auxiliary terminals interfacing with built-in OSL calibration circuits, the present invention enables high precision in calibration operations. The flexible switch network configurations, whether implemented as SP4T or multiple SPST switches offer optimized RF performance for various antenna configurations. Furthermore, the integrated calibration capability facilitates characterization of parasitic effects and comprehensive compensation for manufacturing variations, ensuring consistent performance across different operating conditions. This advanced architecture not only improves fundamental RF metrics but also enables precise, real-time adaptation of antenna characteristics, making it particularly suitable for modern wireless devices that demand optimal RF performance across multiple wireless communication standards.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An aperture tuner circuit, comprising:
a plurality of switching terminals;
at least one auxiliary terminal;
at least one open/short/load (OSL) calibration circuit, connected to the at least one auxiliary terminal and selectively configurable to provide one of a predetermined open path, a predetermined short path and a predetermined load to the aperture tuner circuit; and
a switch network, connected to the plurality of switching terminals, configured to selectively establish and reconfigure signal paths between the switching terminals.

2. The aperture tuner circuit of claim 1, further comprising:
at least one capacitance tuning circuit connected in parallel with the at least one OSL calibration circuit.

3. The aperture tuner circuit of claim 2, wherein the at least one capacitance tuning circuit comprises at least one tunable capacitor.

4. The aperture tuner circuit of claim 3, wherein the at least one capacitance tuning circuit further comprises at least one switch.

5. The aperture tuner circuit of claim 4, wherein the at least one tunable capacitor is connected in parallel with the at least one switch.

6. The aperture tuner circuit of claim 4, wherein the at least one tunable capacitor is connected in series with the at least one switch.

7. The aperture tuner circuit of claim 1, further comprising:
a plurality of auxiliary terminals; and
a plurality of OSL calibration circuits, each connected to a respective one of the plurality of auxiliary terminals;
wherein a first OSL calibration circuit of the plurality of OSL calibration circuits is connected to a first auxiliary terminal of the plurality of auxiliary terminals, and a second OSL calibration circuit of the plurality of OSL calibration circuits is connected to a second auxiliary terminal of the plurality of auxiliary terminals.

8. The aperture tuner circuit of claim 7, further comprising:
a tunable capacitor connected between the first auxiliary terminal and the second auxiliary terminal, configured to adjust an impedance of the aperture tuner circuit.

9. The aperture tuner circuit of claim 7, further comprising:
a plurality of capacitance tuning circuits, each connected in parallel with a respective one of the plurality of OSL calibration circuits;
wherein a first capacitance tuning circuit of the plurality of capacitance tuning circuits is connected in parallel with the first OSL calibration circuit of the plurality of OSL calibration circuits, and a second capacitance tuning circuit of the plurality of capacitance tuning circuits is connected in parallel with the second OSL calibration circuit of the plurality of OSL calibration circuits.

10. The aperture tuner circuit of claim 9, wherein each of the plurality of capacitance tuning circuits comprises at least one tunable capacitor.

11. The aperture tuner circuit of claim 10, wherein each of the plurality of capacitance tuning circuits further comprises at least one switch.

12. The aperture tuner circuit of claim 11, wherein the at least one tunable capacitor is connected in parallel with the at least one switch.

13. The aperture tuner circuit of claim 11, wherein the at least one tunable capacitor is connected in series with the at least one switch.

14. The aperture tuner circuit of claim 1, wherein the switch network comprises:
a plurality of first switches configured as a single-pole, multiple-throw switch, each of the plurality of first switches having a first end connected to a common node and a second end connected to a respective one of the plurality of switching terminals.

15. The aperture tuner circuit of claim 14, further comprising:
a plurality of second switches, each having a first end connected to a ground and a second end connected to a respective one of the plurality of switching terminals.

16. The aperture tuner circuit of claim 1, wherein the switch network comprises:
a plurality of first switches, each configured as a single-pole, single-throw switch and each having a first end connected to a ground and a second end connected to a respective one of the plurality of switching terminals.

17. The aperture tuner circuit of claim 16, further comprising:
a plurality of second switches, each having a first end connected to a ground and a second end connected to a respective one of the plurality of switching terminals.

18. The aperture tuner circuit of claim 1, further comprising:
a controller configured to control configurations of the switch network and the at least one OSL calibration circuit, thereby establishing and reconfiguring the signal paths provided by the switch network and controlling the at least one OSL calibration circuit to provide one of a predetermined open path, a predetermined short path and a predetermined load to the aperture tuner circuit.
